(19) United States
(12) Patent Application Publication
(10) Pub. No.: US 2023/0082659 A1
(43) Pub. Date: Mar. 16, 2023

(54) SUBSTRATE PROCESSING APPARATUS

(71) Applicant: Kioxia Corporation, Tokyo (JP)

(72) Inventor: Masaki SAWADA, Yokkaichi (JP)

(73) Assignee: Kioxia Corporation, Tokyo (JP)

(21) Appl. No.: 17/653,161

(22) Filed: Mar. 2, 2022

(30) Foreign Application Priority Data
Sep. 10, 2021 (JP) 2021-147791

(51) Int. Cl. C23C 16/44

(52) U.S. Cl. CPC C23C 16/4409

(57) ABSTRACT

A substrate processing apparatus according to an embodiment includes a door portion that is arranged so as to be capable of opening and closing an opening portion from inside a second container and is configured to airtightly seal a first container, and the door portion includes a peripheral area that includes a surface facing a side wall of the second container around the opening portion while the door portion is in a closed state, an inside area that is an area surrounded by the peripheral area and includes a surface facing the opening portion while the door portion is in the closed state, a groove portion that is provided in the peripheral area to surround at least part of the inside area and includes a first step and a second step, the second step being positioned closer to the inside area than the first step, and a sealing member that continuously surrounds the inside area at a position closer to the inside area than the first step.

### CROSS-REFERENCE TO RELATED APPLICATIONS

This application is based upon and claims the benefit of priority from Japanese Patent Application No. 2021-147791, filed on Sep. 10, 2021; the entire contents of which are incorporated herein by reference.

### FIELD

Embodiments described herein relate generally to a substrate processing apparatus.

### BACKGROUND

In some cases, some substrate processing apparatuses used for a semiconductor manufacturing process and the like include a plurality of containers such as a container for processing substrates and a container for transferring the substrates. A plurality of containers is connected to each other via an opening portion for transfer of the substrate between the containers, and is airtightly sealed by a door portion provided at the opening portion. However, when the door portion is opened and closed to transfer the substrate, particles may be generated from the door portion, in some cases.

### BRIEF DESCRIPTION OF THE DRAWINGS

FIG. 1 is a top view schematically illustrating an example of an overall configuration of a plasma processing apparatus according to a first embodiment;

FIG. 2 is a cross-sectional view schematically illustrating an example of a configuration of a process chamber of the plasma processing apparatus according to the first embodiment;

FIGS. 3A and 3B are schematic diagrams each illustrating an example of a configuration of a door portion of a transfer chamber according to the first embodiment, the door portion being provided between the transfer chamber and a load lock;

FIGS. 4A to 4C are schematic diagrams illustrating an example of an opening/closing operation of the door portion of the transfer chamber according to the first embodiment;

FIG. 5 is a cross-sectional view illustrating an example of a deposited film formed on the door portion of the transfer chamber according to the first embodiment;

FIG. 6 is a side view illustrating an example of a configuration of a door portion of the transfer chamber according to a first modification of the first embodiment, as viewed from the load lock side;

FIG. 7 is a side view illustrating an example of a configuration of a door portion of the transfer chamber according to a second modification of the first embodiment, as viewed from the load lock side;

FIG. 8 is a side view illustrating an example of a configuration of a door portion of the transfer chamber according to a third modification of the first embodiment, as viewed from the load lock side;

FIGS. 9A and 9B are schematic diagrams each illustrating an example of a configuration of a door portion of the transfer chamber according to a fourth modification of the first embodiment;

FIG. 10 is a side view illustrating an example of a configuration of a door portion of the transfer chamber according to a fifth modification of the first embodiment, as viewed from the load lock side;

FIG. 11 is a side view illustrating an example of a configuration of a door portion of the transfer chamber according to a sixth modification of the first embodiment, as viewed from the load lock side;

FIG. 12 is a side view illustrating an example of a configuration of a door portion of the transfer chamber according to a seventh modification of the first embodiment, as viewed from the load lock side;

FIGS. 13A to 13C are cross-sectional views each illustrating an example of a configuration of a door portion of the transfer chamber according to a second embodiment, the door portion being provided between the transfer chamber and the load lock;

FIG. 14 is a cross-sectional view illustrating an example of a deposited film formed on the door portion of the transfer chamber according to the second embodiment;

FIGS. 15A and 15B are cross-sectional views illustrating examples of configurations of door portions of the transfer chambers according to first and second modifications of the second embodiment;

FIGS. 16A and 16B are cross-sectional views each illustrating an example of a configuration of a door portion of the transfer chamber according to a third embodiment, the door portion being provided between the transfer chamber and the load lock;

FIG. 17 is a cross-sectional view illustrating an example of a deposited film formed on the door portion of the transfer chamber according to the third embodiment;

FIGS. 18A and 18B are cross-sectional views illustrating examples of configurations of door portions of the transfer chambers according to first and second modifications of the third embodiment;

FIG. 19 is a perspective view of a door portion of the transfer chamber according to a third modification of the third embodiment;

FIGS. 20A and 20B are cross-sectional views each illustrating an example of a configuration of a door portion of the transfer chamber according to the third modification of the third embodiment; and

FIGS. 21A and 21B are cross-sectional views illustrating examples of configurations of door portions of the transfer chambers according to fourth and fifth modifications of the third embodiment.

### DETAILED DESCRIPTION

A substrate processing apparatus according to an embodiment includes a first container that is configured to store a substrate, a second container that is connected to the first container via an opening portion through which the substrate is transferred between the first container and the second container, and a door portion that is arranged so as to be capable of opening and closing the opening portion from inside the second container and is configured to airtightly seal the first container, in which the door portion includes a peripheral area that includes a surface facing a side wall of the second container around the opening portion while the door portion is in a closed state, an inside area that is an area surrounded by the peripheral area and includes a surface facing the opening portion while the door portion is in the closed state, a groove portion that is provided in the peripheral area to surround at least part of the inside area and includes a first step and a second step, the second step being positioned closer to the inside area than the first step, and a sealing member that continuously surrounds the inside area at a position closer to the inside area than the first step.

Next, non-limiting exemplary embodiments of the present invention will be described below in detail with reference to the drawings. The present invention is not limited to the following embodiments. Furthermore, component elements in the following embodiments include component elements that are readily conceivable by a person skilled in the art or that are substantially identical.

### First Embodiment

Hereinafter, a first embodiment will be described in detail with reference to the drawings.

### Configuration Example of Plasma Processing Apparatus

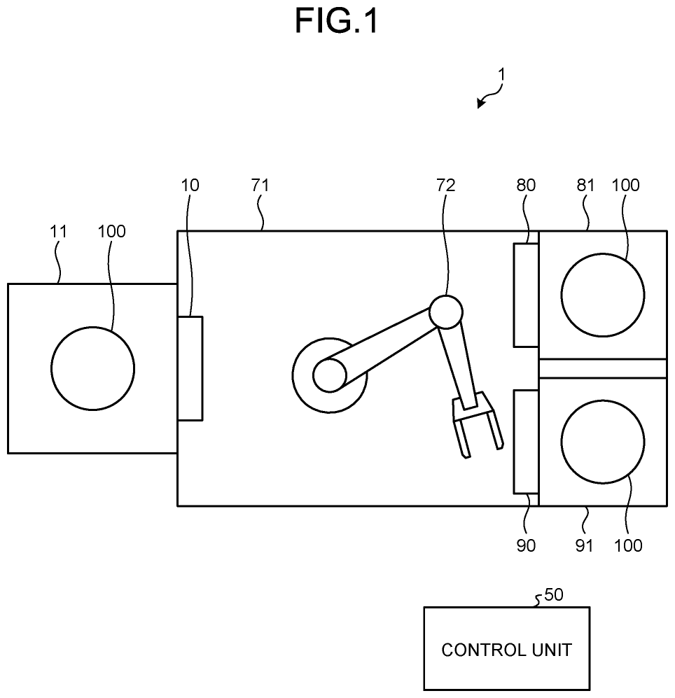

FIG. 1 is a top view schematically illustrating an example of an overall configuration of a plasma processing apparatus 1 according to the first embodiment. As illustrated in FIG. 1, the plasma processing apparatus 1 as the substrate processing apparatus includes a process chamber 11, a transfer chamber 71, load locks 81 and 91, and a control unit 50.

The process chamber 11 as a process container is a container for performing plasma processing on a wafer 100 as a substrate, and is connected to the transfer chamber 71 so as to be airtightly sealed. The wafer 100 stored in the process chamber 11 is subjected to, for example, etching using plasma.

The load lock (L/L) 81 is a storage container for storing the wafer 100 to be processed and is a collection container for collecting the processed wafer 100, and is connected to the transfer chamber 71 in an airtightly sealed manner. The L/L 81 is configured to store a plurality of wafers 100, such as one lot of wafers 100.

The load lock (L/L) 91 is a storage container for storing the wafer 100 to be processed and is a collection container for collecting the processed wafer 100, and is connected to the transfer chamber 71 in an airtightly sealed manner. The L/L 91 is configured to store a plurality of wafers 100, such as one lot of wafers 100.

The transfer chamber 71 is a container for transferring the wafer 100 under reduced pressure, and is configured to be airtightly sealed. The transfer chamber 71 includes a transfer arm 72 that transfers the wafer 100. The transfer arm 72 transfers the wafers 100 from the L/Ls 81 and 91 to the process chamber 11, and from the process chamber 11 to the L/Ls 81 and 91.

In addition, the transfer chamber 71 includes door portions 10, 80, and 90 that are provided openably and closably with respect to opening portions, which are not illustrated, positioned between the transfer chamber 71 and the process chamber 11 and between the transfer chamber 71 and the L/Ls 81 and 91. Opening and closing these door portions 10, 80, and 90 allows transfer of the wafers 100 to and from the process chamber 11 and the L/Ls 81 and 91 via the respective opening portions and airtight sealing of the process chamber 11 and the L/Ls 81 and 91 from each other.

The control unit 50 controls each unit of the plasma processing apparatus 1, including the transfer arm 72 and the door portions 10, 80, and 90. The control unit 50 is configured as a computer including a central processing unit (CPU), a read only memory (ROM), a random access memory (RAM), and the like, which are not illustrated.

However, the control unit 50 may be configured as an application specific integrated circuit (ASIC) or the like having a function for use in the plasma processing apparatus 1.

Note that the configuration of the plasma processing apparatus 1 illustrated in FIG. 1 is merely an example, and is not limited to the above example, for example, in the shape of the transfer chamber 71, the arrangement of the process chamber 11 and the L/Ls 81 and 91 with respect to the transfer chamber 71, and the like. In addition, any number of the process chambers 11 and the L/Ls 81 and 91 may be employed, and at least anyone of a plurality of the process chambers 11 and the L/Ls 81 and 91 may be connected to the transfer chamber 71.

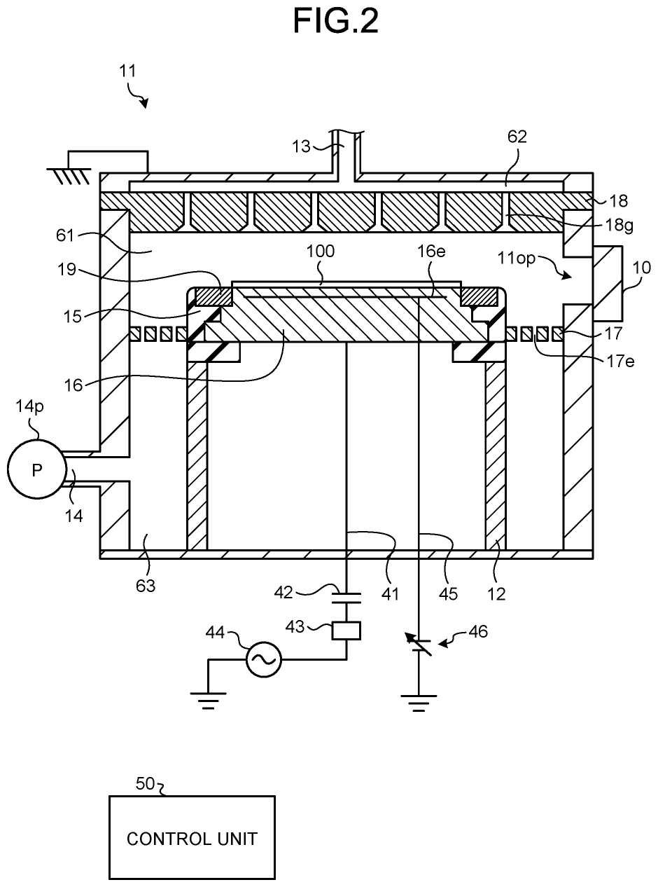

FIG. 2 is a cross-sectional view schematically illustrating an example of a configuration of the process chamber 11 of the plasma processing apparatus 1 according to the first embodiment. The process chamber 11 is configured to perform, for example, etching using plasma, and the plasma processing apparatus 1 is configured as, for example, an etching apparatus.

As illustrated in FIG. 2, the plasma processing apparatus 1 includes the process chamber 11 for processing the wafer 100. The process chamber 11 is made of, for example, aluminum and is configured to be airtightly sealed.

The process chamber 11 has a side surface that is provided with an opening portion 11op for transfer of the wafer 100 to and from the transfer chamber 71. The opening portion 11op is provided with the door portion 10 on the side of the transfer chamber 71. The door portion 10 includes a sealing member which is not illustrated, and is configured to airtightly seal the process chamber 11 and to be capable of opening and closing to transfer the wafer 100 through the opening portion 11op.

A gas supply port 13 is provided in an upper portion of the process chamber 11. The gas supply port 13 is connected to a gas supply device which is not illustrated through a pipe to supply a process gas used to process the wafer 100.

A shower head 18 that functions as an upper electrode is provided below the gas supply port 13. The shower head 18 is provided with a plurality of gas ejection holes 18g that penetrates the shower head 18 in a plate thickness direction. The process gas supplied from the gas supply port 13 is introduced into the process chamber 11 via the gas ejection holes 18g.

An electrostatic chuck 16 is arranged under the shower head 18 so as to face the shower head 18. The electrostatic chuck 16 horizontally supports the wafer 100 to be processed, in the process chamber 11, electrostatically attracts the wafer 100, and also functions as a lower electrode.

The electrostatic chuck 16 is supported on a support portion 12 protruding vertically upward from a bottom wall near the center of the process chamber 11 into a cylindrical shape. The support portion 12 supports the electrostatic chuck 16 near the center of the process chamber 11 at a predetermined distance from the shower head 18 so that the electrostatic chuck 16 faces the shower head 18 in parallel. In such a structure, the shower head 18 and the electrostatic chuck 16 constitute a pair of parallel plate electrodes.

Furthermore, the electrostatic chuck 16 includes a chuck mechanism that electrostatically attracts the wafer 100. The chuck mechanism includes a chuck electrode 16e, a feeder 45, and a power supply 46. The power supply 46 is connected to the chuck electrode 16e via the feeder 45. Such a mechanism supplies DC power from the power supply 46 to the chuck electrode 16e, electrostatically charge an upper surface of the electrostatic chuck 16, and attracts the wafer 100.

A feeder 41 is connected to the electrostatic chuck 16. A blocking capacitor 42, a matching device 43, and a high frequency power supply 44 are connected to the feeder 41. In plasma processing, high frequency power having a predetermined frequency is supplied from the high frequency power supply 44 to the electrostatic chuck 16. Such a mechanism causes the electrostatic chuck 16 to function as the lower electrode. Furthermore, such a configuration provides the plasma processing apparatus 1 configured as, for example, a plasma processing apparatus having power applied from the lower side.

However, the feeder 41 including the blocking capacitor 42, the matching device 43, the high frequency power supply 44, and the like may be connected to the shower head 18 functioning as the upper electrode so that the plasma processing apparatus 1 may be configured as a plasma processing apparatus having power applied from the upper side.

Alternatively, the feeder 41 including the blocking capacitor 42, the matching device 43, the high frequency power supply 44, and the like may be connected to both of the electrostatic chuck 16 and the shower head 18 so that the plasma processing apparatus 1 may be configured as a plasma processing apparatus having power applied from the upper and lower sides.

The electrostatic chuck 16 has an outer periphery on which an insulator ring 15 is arranged to cover a side surface and the peripheral edge of a bottom surface of the electrostatic chuck 16. A peripheral ring 19 is provided above the insulator ring 15 to surround the outer periphery of the electrostatic chuck 16.

The peripheral ring 19 includes, for example, a silicon-based material, and adjusts an electric field in order for the electric field not to be deflected in a vertical direction at the peripheral edge of the wafer 100, that is, in a direction perpendicular to a surface of the wafer 100, while etching the wafer 100.

A baffle plate 17 is provided between the insulator ring 15 and a side wall of the process chamber 11. The baffle plate 17 has a plurality of gas exhaust holes 17e penetrating the baffle plate 17 in a plate thickness direction.

A gas exhaust port 14 is provided below the baffle plate 17 in the process chamber 11. A vacuum pump 14p that exhausts the atmosphere in the process chamber 11 is connected to the gas exhaust port 14.

An area in the process chamber 11 partitioned by the electrostatic chuck 16, the baffle plate 17, and the shower head 18 serves as a plasma processing chamber 61. An upper area in the process chamber 11 partitioned by the shower head 18 serves as a gas supply chamber 62. A lower area in the process chamber 11 partitioned by the electrostatic chuck 16 and the baffle plate 17 serves as a gas exhaust chamber 63.

The control unit 50 described above controls the power supply 46, the matching device 43, the high frequency power supply 44, the gas supply device, and the like.

In plasma processing of the wafer 100, according to the control of the control unit 50, the wafer 100 to be processed is placed on the electrostatic chuck 16 and attracted by the chuck mechanism. Furthermore, the inside of the process chamber 11 is evacuated by the vacuum pump 14p connected to the gas exhaust port 14. When the inside of the process chamber 11 reaches a predetermined pressure, the process gas is supplied from the gas supply device, which is not illustrated, to the gas supply chamber 62, and the process gas is further supplied to the plasma processing chamber 61 via the gas ejection holes 18g of the shower head 18.

In addition, according to the control of the control unit 50, a high-frequency voltage is applied to the electrostatic chuck 16 as the lower electrode while the shower head 18 as the upper electrode is grounded, generating plasma in the plasma processing chamber 61. On the lower electrode side, a potential gradient is generated between the plasma and the wafer 100 by self-bias due to a high-frequency voltage, ions in the plasma are accelerated to the electrostatic chuck 16, and anisotropic etching is performed.

### Configuration Example of Door Portion

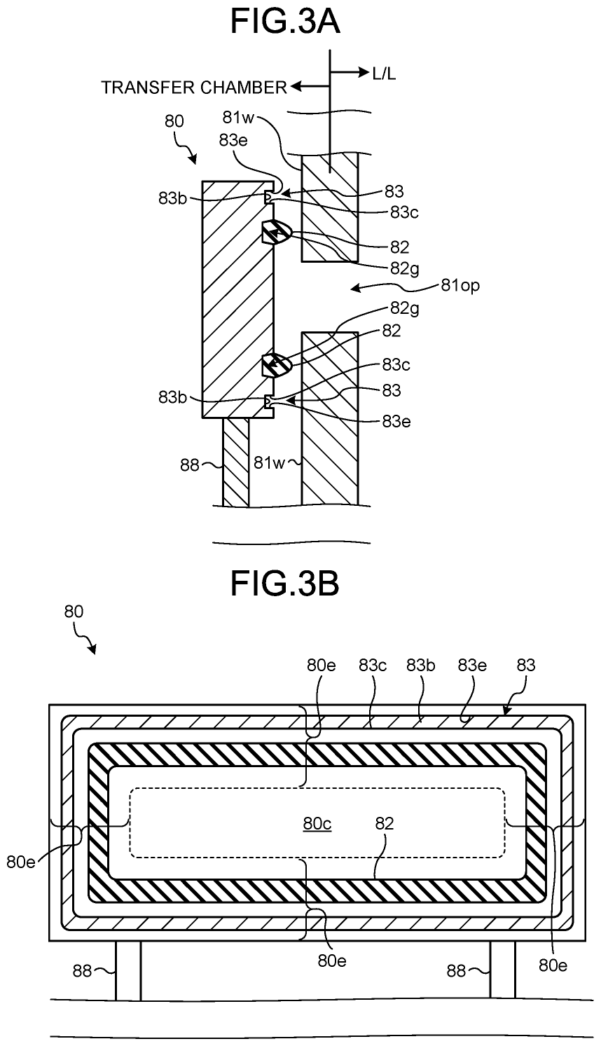

Next, a detailed configuration example of the door portion 80 of the transfer chamber 71 provided between the transfer chamber 71 and the L/L 81 will be described with reference to FIGS. 3A to 5.

FIGS. 3A and 3B are schematic diagrams each illustrating an example of a configuration of the door portion 80 of the transfer chamber 71 according to the first embodiment, the door portion 80 being provided between the transfer chamber 71 and the L/L 81. FIG. 3A is a cross-sectional view of the door portion 80, and FIG. 3B is a side view of the door portion 80 as viewed from the L/L 81.

A side wall 81w illustrated in FIG. 3A is a side wall on a side on which the transfer chamber 71 is connected to the L/L 81, and includes an opening portion 81op opened toward the L/L 81. However, the side wall 81w between the transfer chamber 71 and the L/L 81 may be shared between the transfer chamber 71 and the L/L 81.

As illustrated in FIG. 3A, for example, the door portion 80 is supported by a shaft 88 that drives the door portion 80 up and down and left and right of the drawing. FIG. 3A illustrates the door portion 80 in the middle of an opening/closing operation with respect to the opening portion 81op. The opening/closing operation of the door portion 80 will be described in detail later.

The door portion 80 is formed into, for example, a rectangular flat plate shape using an aluminum member as a main body, and includes a sealing member 82, a shallow groove 82g, and a groove portion 83 on a surface facing toward the L/L 81. The door portion 80 may have a film such as an aluminum oxide film, on a base material such as aluminum.

As illustrated in FIGS. 3A and 3B, the sealing member 82 is provided in a peripheral area 80e of the door portion 80 and continuously surrounds an inside area 80c of the door portion 80. The peripheral area 80e of the door portion 80 is an area that includes a surface facing toward the L/L 81 and while the door portion 80 is in a closed state, facing the side wall 81w around the opening portion 81op. The inside area 80c of the door portion 80 is an area that is surrounded by the peripheral area 80e and includes a surface facing toward the L/L 81 and while the door portion 80 is in the closed state, facing the opening portion 81op.

More specifically, the sealing member 82 is embedded in the shallow groove 82g and protruded toward the side wall 81w on a surface of the door portion 80 facing toward the L/L 81. The sealing member 82 may protrude so that the thickness in a width direction decreases toward the front end.

The shallow groove 82g is provided in the peripheral area 80e of the door portion 80 so as to have a recess in a surface of the door portion 80 facing toward the L/L 81, and is arranged into a frame shape continuously surrounding the inside area 80c of the door portion 80. The sealing member 82 is configured, for example, as an O-ring or the like that is obtained by hot compression molding of an elastic resin material or the like put into the shallow groove 82g by using a mold or the like. When the resin material is arranged, an adhesive may be applied to the inside of the shallow groove 82g to temporarily fix the resin material.

The groove portion 83 is provided so as to have a recess in a surface of the door portion 80 facing toward the L/L 81. The groove portion 83 is, for example, formed deeper than the shallow groove 82g described above. The groove portion 83 is provided at a position further outside the sealing member 82, in the peripheral area 80e of the door portion 80, and continuously surrounds the inside area 80c of the door portion 80.

More specifically, the groove portion 83 includes, for example, a step 83e on a side farther away from the inside area 80c, a step 83c on a side closer to the inside area 80c than the step 83e, and a bottom surface 83b between these steps 83e and 83c. For example, each of the steps 83e and 83c is formed in a planar shape substantially perpendicular to the surface of the door portion 80 on the side of the L/L 81, and the bottom surface 83b is formed in a planar shape substantially horizontal to the surface of the door portion 80 on the side of the L/L 81. Therefore, for example, corner portions are formed at substantially right angle, at connection portions between the step 83e and the bottom surface 83b and between the step 83e and the bottom surface 83b.

However, regardless of the example of FIG. 3A, the groove portion 83 may have various cross-sectional shapes. For example, the steps 83e and 83c may have a tapered shape inclined in directions approaching each other or directions away from each other, from the surface of the door portion 80 on the side of the L/L 81 toward the bottom surface 83b. Furthermore, each of the steps 83e and 83c may have a curved surface shape. The steps 83e and 83c may be connected to each other without the flat bottom surface 83b so that the groove portion 83 may have a U-shaped or V-shaped cross-sectional shape.

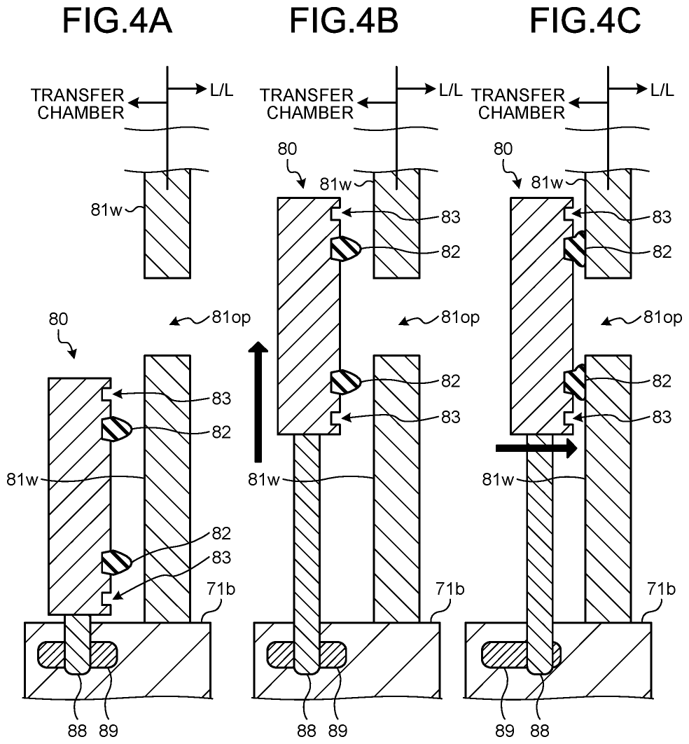

FIGS. 4A to 4C are schematic diagrams illustrating an example of the opening/closing operation of the door portion 80 of the transfer chamber 71 according to the first embodiment, the door portion 80 being provided between the transfer chamber 71 and the L/L 81. FIG. 4A illustrates a cross-section of the door portion 80 in an opened state, FIG. 4B illustrates the door portion 80 in the middle of the opening/closing operation, and FIG. 4C illustrates a cross-section of the door portion 80 in the closed state.

As illustrated in FIGS. 4A to 4C, the shaft 88 supporting the door portion 80 is connected to, for example, a base portion 89 embedded in a bottom portion 71b constituting a floor of the transfer chamber 71.

In addition, the shaft 88 drives the door portion 80 in a direction approaching or moving away from the bottom portion 71b of the transfer chamber 71 and in a direction approaching or moving away from the L/L 81 by a drive mechanism such as an air-driven cylinder which is not illustrated. In other words, the shaft 88 drives the door portion 80 in a vertical direction and a horizontal direction in the drawing.

As illustrated in FIG. 4A, in the opened state of the door portion 80, the door portion 80 stands by at a position near the bottom portion 71b of the transfer chamber 71 below the opening portion 81op and away from the side wall 81w by a predetermined distance. In other words, the door portion 80 stands by at a position diagonally below the opening portion 81op. This configuration makes it possible to open the opening portion 81op and transfer the wafer 100 between the transfer chamber 71 and the L/L 81.

As illustrated in FIG. 4B, upon shifting from the opened state to the closed state, the door portion 80 is driven to a height position of the opening portion 81op. At this time point, the door portion 80 is still away from the side wall 81w by a predetermined distance. This configuration makes it possible to drive the door portion 80 upward while maintaining a non-contact state between the sealing member 82 protruding from a main body of the door portion 80 and the side wall 81w.

As illustrated in FIG. 4C, at the height position of the opening portion 81op, the door portion 80 is driven in a direction approaching the side wall 81w. Therefore, the sealing member 82 protruding from the main body of the door portion 80 toward the side wall 81w touches on and compressed against the side wall 81w around the opening portion 81op, thus airtightly sealing the L/L 81. At this time, the main body of the door portion 80 does not makes contact with the side wall 81w, and the main body of the door portion 80 and the side wall 81w face each other across a small gap.

As described above, the closing operation of the door portion 80 is performed. On the other hand, when the opening operation of the door portion 80 is performed, the above operation is reversely performed from FIG. 4C to FIG. 4B and further to FIG. 4A. In other words, the door portion 80 in which the sealing member 82 touches on the side wall 81w is driven in a direction away from the side wall 81w, further driven toward the bottom portion 71b of the transfer chamber 71 below the opening portion 81op, thus, the door portion 80 becomes in opening state, and the opening portion 81op is opened.

Note that, in the plasma processing apparatus 1 according to the first embodiment, for example, in a normal state, the door portion 80 is in the closed state, that is, in a state illustrated in FIG. 4C, and is temporarily brought into the opened state in the opening/closing operation mainly performed in transfer of the wafer 100.

Furthermore, regardless of the examples of FIGS. 4A to 4C, the door portion 80 may be driven upward with respect to the opening portion 81op so as to be opened and closed. In this configuration, arranging the base portion 89 of the shaft 88 at, for example, at a ceiling portion of the transfer chamber 71 makes it possible to move the door portion 80 upward and downward and horizontally by the shaft 88.

Furthermore, when the door portion 80 is moved between a position closer to the opening portion 81op and the position diagonally below or a position diagonally above the opening portion 81op, the door portion 80 may be driven linearly between the position closer to the opening portion 81op and the position diagonally below or diagonally above the opening portion 81op, instead of driving the door portion 80 in the vertical direction and the horizontal direction.

However, as in the example of FIGS. 4A to 4C, moving the door portion 80 to the position diagonally below the wafer 100 not above the wafer 100 during transfer of the wafer 100 suppresses contamination from the door portion 80 to the wafer 100.

Meanwhile, when plasma processing is performed on the wafer 100 in the process chamber 11 described above, various reaction products are generated by plasma reaction. Some of these reaction products have a relatively low vapor pressure and have the property of readily forming a deposited film. Most of such reaction products are evacuated from the process chamber 11 by the vacuum pump 14p connected to the process chamber 11.

However, some of the reaction products may remain in the atmosphere in the process chamber 11 even after the plasma processing on the wafer 100 and flow out into the transfer chamber 71 when the wafer 100 is transferred to and from the transfer chamber 71.

Thus, the reaction products are deposited in the transfer chamber 71, and form, for example, the deposited film containing components such as tungsten and titanium contained in an etching target on the wafer 100 or components such as fluorine contained in the process gas used for etching. In some cases, the deposited film is also formed on the door portion 80 and on the side wall 81w positioned on the side of the L/L 81, which are described above.

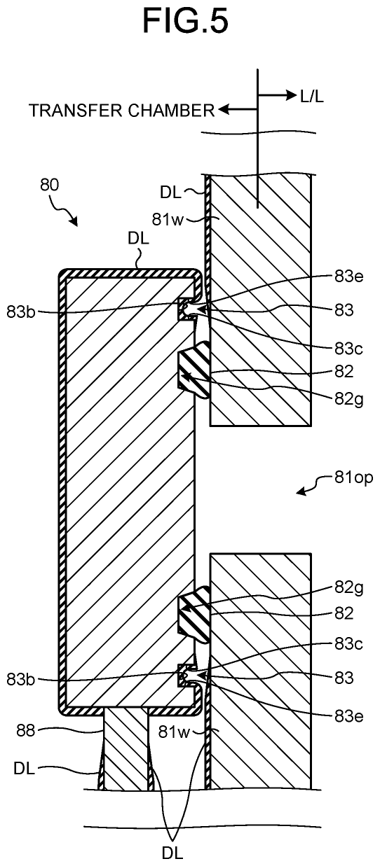

FIG. 5 is a cross-sectional view illustrating an example of the deposited film DL formed on the door portion 80 of the transfer chamber 71 according to the first embodiment, the door portion 80 being provided between the transfer chamber 71 and the L/L 81. As illustrated in FIG. 5, due to the deposition of the reaction products, the deposited film DL is formed on a surface of the side wall 81w on the side of the transfer chamber 71, and on the shaft 88, the door portion 80, and the like. As described above, for example, the closed state of the door portion 80 is the normal state, and the deposited film DL is mainly formed on a surface of the door portion 80 being in the closed state.

Here, the deposited film DL is formed not only on a surface of the door portion 80 facing the transfer chamber 71 and on end surfaces of the door portion 80 in a vertical direction but also, for example, on a part of the surface of the door portion 80 facing the L/L 81, in some cases. This is because the atmosphere containing the reaction products may flow into the gap between the door portion 80 and the side wall 81w, from the end surfaces of the door portion 80 in the vertical direction.

However, the atmosphere containing the reaction products remains, for example, in a space of the groove portion 83 provided outside the sealing member 82 and surrounding the sealing member 82. At this time, most of the reaction products remaining in the atmosphere is consumed due to being deposited on the steps 83e and 83c, the bottom surface 83b, and the like of the groove portion 83. Therefore, the atmosphere flowing into an area inward from the groove portion 83 contains few reaction products, and the deposited film DL is hardly formed on the surfaces of the door portion 80 and the side wall 81w facing each other on the inside from the groove portion 83.

As described above, the door portion 80 of the transfer chamber 71 according to the first embodiment consumes the reaction products in the atmosphere, in the groove portion 83, and suppresses the formation of the deposited film DL in the area inward from the groove portion 83.

The example of the configuration of the door portion 80 of the transfer chamber 71 according to the first embodiment, the door portion 80 being provided between the transfer chamber 71 and the L/L 81 has been described above. Note that the door portion 90 of the transfer chamber 71 provided between the transfer chamber 71 and the L/L 91 may also have a similar configuration to that of the door portion 80 described above.

### Review of Plasma Processing Apparatus

In a semiconductor device manufacturing process, for example, the plasma processing apparatus in which the process chamber, L/L, and the like are connected to each other via the transfer chamber is used, in some cases. The transfer chamber includes, for example, the opening portion between the process chamber and the L/L or the like, and the door portion that is capable of opening and closing the opening portion.

In addition, during plasma processing, the reaction products generated in the process chamber flows out into the transfer chamber, and the deposited film may be formed on the side wall of the transfer chamber, a door portion of the transfer chamber, and the like. In some cases, such a deposited film is also formed on the surfaces of the door portion and the side wall around the opening portion, which face each other, and the surface of the sealing member facing the gap between the door portion and the side wall.

Here, when the door portion in the closed state is brought into the opened state, the sealing member touching on the side wall is released from the compressed state. At this time, in a case where the deposited film is formed on the surface of the sealing member, the deposited film may be cracked and peeled off, when the sealing member returns to the original shape thereof. Alternatively, the deposited film may be scattered around by an elastic force of the sealing member. The peeled or scattered deposited film may become particles and attach to the wafer in the transfer chamber.

The plasma processing apparatus 1 according to the embodiment includes the groove portion 83 that is provided in the peripheral area 80e of the door portion 80 to surrounds the inside area 80c, and the sealing member 82 that continuously surrounds the inside area 80c at a position closer to the inside area 80c than the groove portion 83. This configuration makes it possible to suppress the generation of particles from the door portion 80.

### First to Third Modifications

In the first embodiment described above, the groove portion 83 continuously surrounds the inside area 80c of the door portion 80. However, the groove portion may be configured to surround part of the inside area of the door portion.

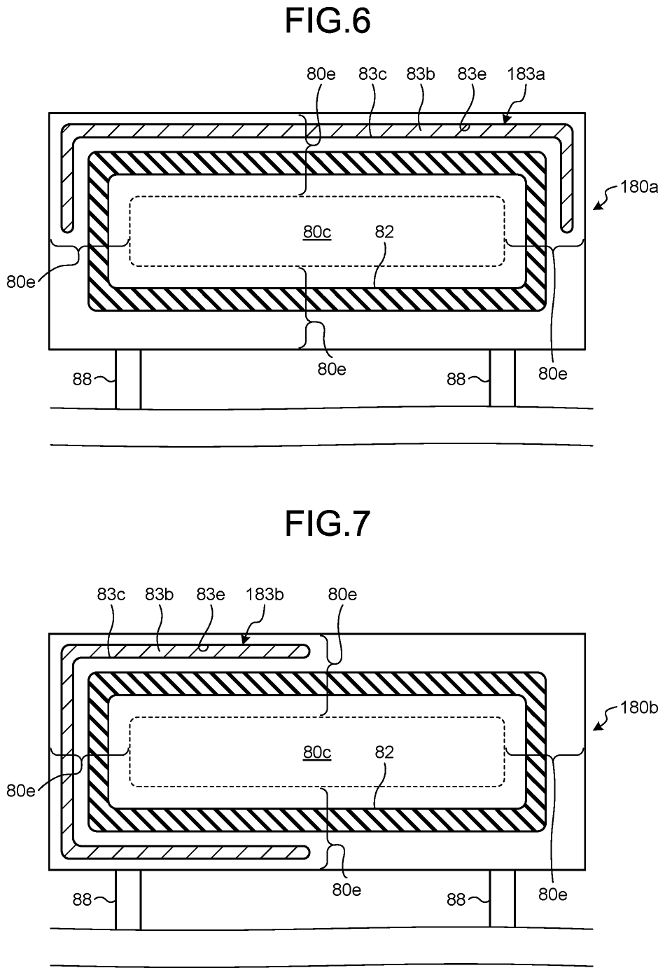

FIGS. 6 to 8 are side views illustrating examples of the configurations of door portions 180a to 180c of the transfer chambers according to first to third modifications of the first embodiment, each viewed from the L/L side, the door portions 180a to 180c each being provided between the transfer chamber and the L/L. Note that in FIGS. 6 to 8, the same reference numerals and symbols are assigned to the same configurations as those of the first embodiment described above, and the description thereof will be omitted.

As illustrated in FIG. 6, the door portion 180a according to the first modification includes a groove portion 183a that is provided in the peripheral area 80e of the door portion 180a to surround an upper side of the inside area 80c.

Depending on the arrangement or the like of a mechanism of exhausting the transfer chamber, uneven flow of the atmosphere containing the reaction products may be caused, and for example, a forming rate of the deposited film may be different in the vertical direction of the door portion 180a. The groove portion 183a surrounding part of the inside area 80c on one side in the vertical direction, as described in the first modification, can be applied to a case where there is a difference in the formation rate of the deposited film in the vertical direction. In other words, the groove portion 183a can be arranged on a side where the deposited film is more easily formed.

As illustrated in FIG. 7, the door portion 180b according to the second modification includes a groove portion 183b that is provided in the peripheral area 80e of the door portion 180b to surround one side of the inside area 80c in the horizontal direction.

Depending on a relative position or the like between the process chamber and the L/L, which are connected to the transfer chamber, the atmosphere containing the reaction products mainly reaches the door portion 180b from one side in the horizontal direction and the formation rate of the deposited film is, for example, different in the horizontal direction of the door portion 180b, in some cases. The groove portion 183b surrounding part of the inside area 80c on one side in the horizontal direction, as described in the second modification, can be applied to a case where there is a difference in the formation rate of the deposited film in the horizontal direction. In other words, for example, the groove portion 183b can be arranged on a side, closer to the process chamber, where the deposited film is more easily formed.

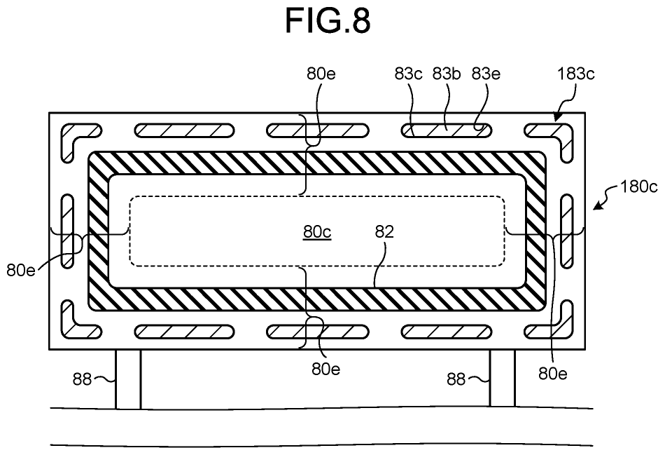

As illustrated in FIG. 8, the door portion 180c according to the third modification includes groove portion 183c that is provided in the peripheral area 80e of the door portion 180c to intermittently surround the inside area 80c.

Depending on the amount of the reaction products flowing out into the transfer chamber, the amount of the deposited film formed on the door portion 180c may be relatively small. The groove portion 183c intermittently surrounding the inside area 80c, as described in the third modification, can be applied to a case where the amount of the deposited film is relatively small. In other words, in the configuration of the third modification, a total length of the groove portion 183c is adjusted according to the amount of the deposited film.

The plasma processing apparatuses including the door portions 180a to 180c according to the first to third modifications have similar effects to those of the plasma processing apparatus 1 according to the first embodiment described above.

### Fourth Modification

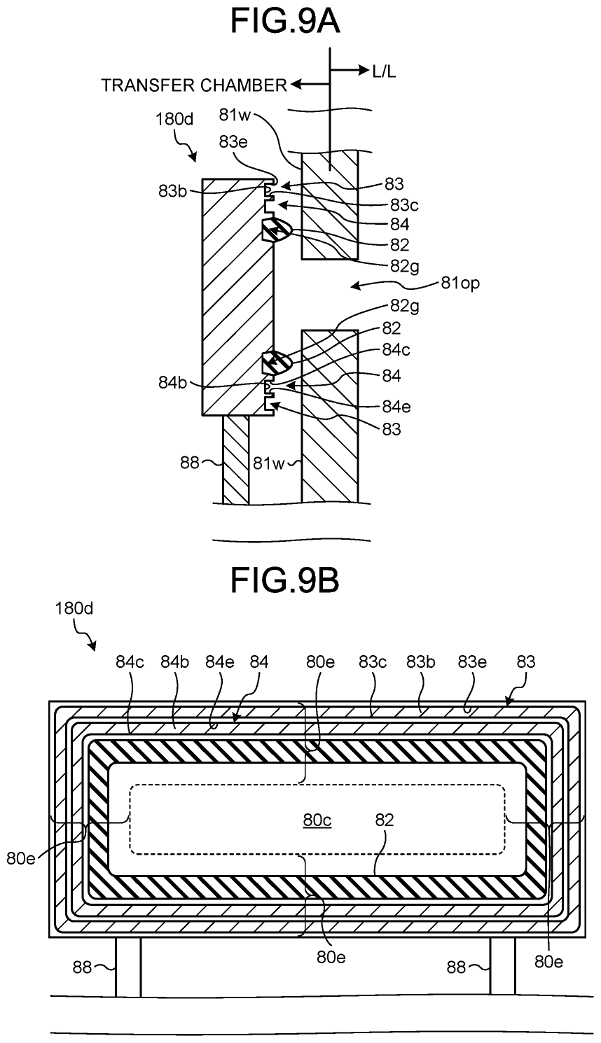

Next, a door portion 180d according to a fourth modification will be described with reference to FIGS. 9A and 9B. The door portion 180d according to the fourth modification is different from the door portion 80 of the first embodiment described above in that the door portion 180d includes a plurality of groove portions 83 and 84.

FIGS. 9A and 9B are schematic diagrams each illustrating an example of a configuration of the door portion 180d of the transfer chamber according to the fourth modification of the first embodiment, the door portion 180d being provided between the transfer chamber and the L/L. FIG. 9A is a cross-sectional view of the door portion 180d, and FIG. 9B is a side view of the door portion 180d as viewed from the L/L side. Note that in FIGS. 9A and 9B, the same reference numerals and symbols are assigned to the same configurations as those of the first embodiment described above, and the description thereof will be omitted.

As illustrated in FIGS. 9A and 9B, the door portion 180d according to the fourth modification includes the plurality of groove portions 83 and 84.

The groove portion 83 is provided in the peripheral area 80e of the door portion 180d to continuously surround the inside area 80c. Furthermore, the groove portion 83 includes the step 83e on a side farther away from the inside area 80c, the step 83c on a side closer to the inside area 80c than the step 83e, and the bottom surface 83b between the steps. However, the steps 83e and 83c may be directly connected so that the groove portion 83 may not have the bottom surface 83b.

The groove portion 84 is provided in the peripheral area 80e on a side closer to the inside area 80c than the groove portion 83 to continuously surround the inside area 80c. The groove portion 84 has a similar configuration, for example, to that of the groove portion 83. In other words, the groove portion 84 includes a step 84e on a side farther away from the inside area 80c, a step 84c on a side closer to the inside area 80c than the step 84e, and a bottom surface 84b between the steps. However, the steps 84e and 84c may be directly connected so that the groove portion 84 may not have the bottom surface 84b.

In the door portion 180d of the fourth modification, the sealing member 82 continuously surrounds the inside area 80c at a position closer to the inside area 80c than the groove portion 84.

According to the plasma processing apparatus of the fourth modification, the door portion 180d includes the groove portion 83, and the groove portion 84 that is arranged closer to the inside area 80c than the groove portion 83. This configuration makes it possible to further increase the effect of trapping the reaction products by using the groove portions 83 and 84, more reliably suppressing the generation of particles from the door portion 180d.

### Fifth to Seventh Modifications

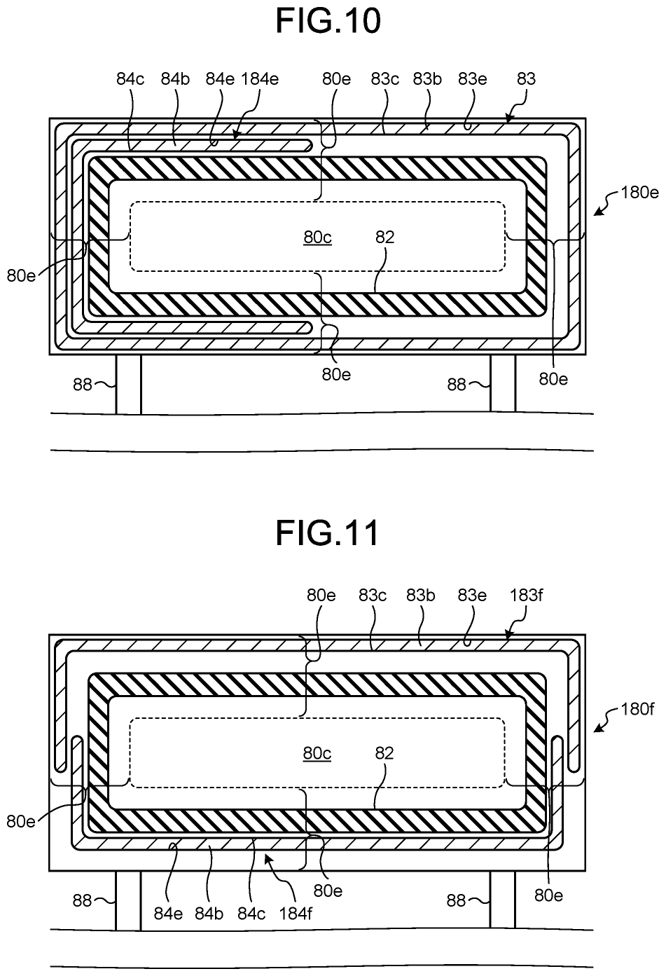

Next, door portions 180e to 180g according to fifth to seventh modifications will be described with reference to FIGS. 10 to 12. Each of the door portions 180e to 180g according to the fifth to seventh modifications is different from the door portion 180d of the fourth modification of the first embodiment described above in that at least one of a plurality of groove portions surrounds part of the inside area 80c of each of the door portions 180e to 180g.

FIGS. 10 to 12 are side views illustrating examples of configurations of the door portions 180e to 180g of the transfer chambers according to the fifth to seventh modifications of the first embodiment, as viewed from the L/L side, the door portions 180e to 180g each being provided between the transfer chamber and the L/L. Note that in FIGS. 10 to 12, the same reference numerals and symbols are assigned to the same configurations to those of the fourth modification described above, and the description thereof will be omitted.

As illustrated in FIG. 10, the door portion 180e according to the fifth modification includes the groove portion 83 that is provided in the peripheral area 80e of the door portion 180e to continuously surround the inside area 80c, and a groove portion 184e that is provided in the peripheral area 80e on a side closer to the inside area 80c than the groove portion 83 to surround one side of the inside area 80c in the horizontal direction.

As described above, for example, the reaction products may mainly flow from a side where the process chamber is arranged. In such a case, as describing in the fifth modification, for example, a plurality of the groove portions 83 and 184e can be arranged in a double manner on a side closer to the process chamber where the deposited film is more easily formed.

As illustrated in FIG. 11, the door portion 180f according to the sixth modification includes a groove portion 183f that is provided in the peripheral area 80e of the door portion 180f to surround an upper side of the inside area 80c, and a groove portion 184f that is provided in the peripheral area 80e on a side closer to the inside area 80c than the groove portion 183f to surround a lower side of the inside area 80c.

At this time, it is preferable to arrange the respective groove portions 183f and 184f so that a portion where the groove portion 183f is not arranged and a portion where the groove portion 184f is not arranged do not overlap when viewed from the center of the inside area 80c. In other words, the groove portions 183f and 184f are arranged so that the groove portions 183f and 184f are overlapped at a boundary between the portion where the groove portion 183f is arranged and the portion where the groove portion 184f is arranged.

In the example of FIG. 11, when viewed from the center of the inside area 80c, lower end portions of the groove portion 183f on both sides in the horizontal direction and upper end portions of the groove portion 184f on both sides in the horizontal direction are arranged in a double manner. This configuration traps the reaction products more reliably.

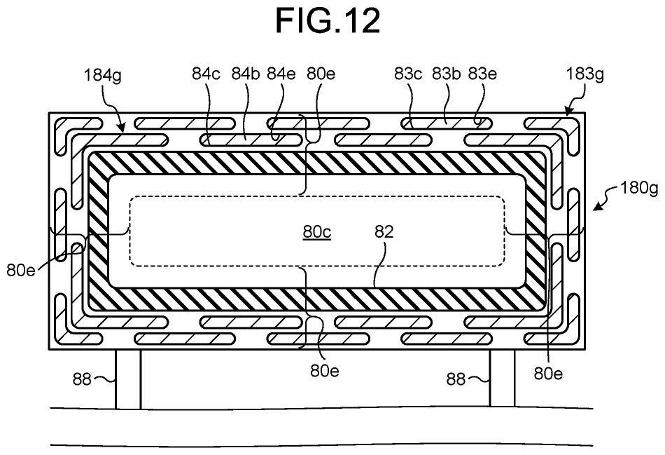

As illustrated in FIG. 12, the door portion 180g according to the seventh modification includes a groove portion 183g and a groove portion 184g that are provided in the peripheral area 80e of the door portion 180g to intermittently surround the inside area 80c.

Even in such a configuration, it is preferable to arrange the groove portion 183g and the groove portion 184g so that a portion where the groove portion 183g breaks and a portion where the groove portion 184g breaks are not arranged in a double manner when viewed from the center of the inside area 80c.

In other words, for example, the groove portion 183g and the groove portion 184g are alternately arranged in the circumferential direction so that the groove portion 184g is arranged at positions corresponding to portions where the groove portion 183g breaks, and the groove portion 183g is arranged at positions corresponding to portions the groove portion 184g breaks, when viewed from the center of the inside area 80c. This configuration traps the reaction products more reliably.

The plasma processing apparatuses including the door portions 180e to 180g according to the fifth to seventh modifications have similar effects to those of the plasma processing apparatus according to the fourth modification described above.

Note that, the door portion is not limited to the examples of the door portions 180d to 180g of the fourth to seventh modifications, and may have three or more groove portions surrounding the inside area 80c in a multiple manner. In this configuration, at least any of the plurality of groove portions may surround part of the inside area 80c or intermittently surround the inside area 80c.

### Second Embodiment

Hereinafter, a second embodiment will be described in detail with reference to the drawings. A plasma processing apparatus according to the second embodiment is different from the plasma processing apparatus according to the first embodiment described above in that a door portion having a sealing member arranged in a groove is provided.

### Configuration Example of Door Portion

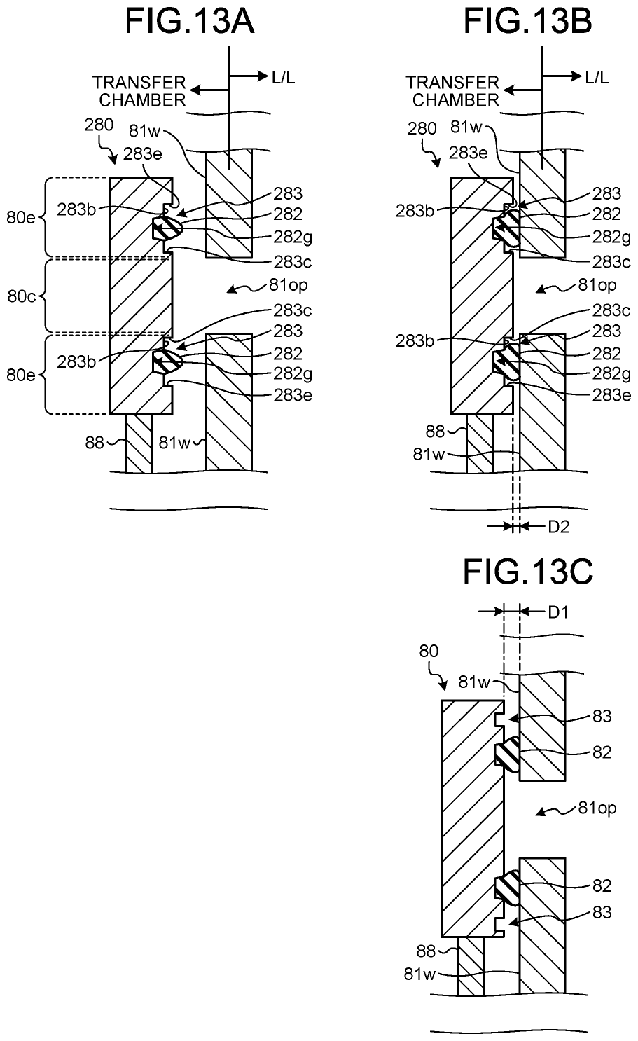

FIGS. 13A to 13C are cross-sectional views each illustrating an example of a configuration of the door portion 280 of the transfer chamber according to the second embodiment, the door portion 280 being provided between the transfer chamber and the L/L. Note that in FIGS. 13A to 13C, the same reference numerals and symbols are assigned to the same configurations to those of the first embodiment described above, and the description thereof will be omitted.

FIG. 13A illustrates a cross-section of the door portion 280 in an opened state, and FIG. 13B illustrates a cross-section of the door portion 280 in a closed state. Furthermore, FIG. 13C illustrates the door portion 80 of the first embodiment described above, for comparison, and shows a cross-section of the door portion 80 in the closed state, as in FIG. 4C described above.

As illustrated in FIGS. 13A and 13B, the door portion 280 includes a groove portion 283 provided in the peripheral area 80e of the door portion 280 to continuously surround the inside area 80c. The sealing member 282 is arranged in the groove portion 283.

More specifically, the groove portion 283 includes a step 283e on a side farther away from the inside area 80c, a step 283c on a side closer to the inside area 80c than the step 283e, and a bottom surface 283b between these steps 283e and 283c. However, the steps 283e and 283c may be directly connected so that the groove portion 283 may not have the bottom surface 283b.

Furthermore, on the bottom surface 283b of the groove portion 283, a shallow groove 282g is arranged that is obtained by further forming a recess in the bottom surface 283b. Similarly to the shallow groove 82g in the first embodiment described above, the shallow groove 282g is formed into a frame shape continuously surrounding the inside area 80c of the door portion 280. The sealing member 282 is embedded in the shallow groove 282g and protruded toward the side wall 81w on a surface of the door portion 280 facing toward the L/L. Thus, the sealing member 282 is arranged closer to the inside area 80c than the step 283e of the groove portion 283, that is, between the step 283c and the step 283e in the groove portion 283.

As illustrated in FIG. 13B, in the closed state of the door portion 280, a distance D2 between the main body of the door portion 280 and the side wall 81w is smaller than, for example, a distance D1 between the main body of the door portion 80 and the side wall 81w in the first embodiment described above. In other words, the main body of the door portion 280 and the side wall 81w face each other across a smaller gap.

This is, for example, an example of a configuration where an amount of protrusion of the sealing member 282 from the bottom surface 283b of the groove portion 283 is substantially equal to an amount of protrusion of the sealing member 82 on the surface of the door portion 80 facing toward the L/L 81 in the first embodiment. In other words, in this configuration, the amount of protrusion of the sealing member 282 on the surface of the door portion 280 facing toward the L/L is smaller than the amount of protrusion of the sealing member 82 on the surface of the door portion 80 facing toward the L/L 81 in the first embodiment.

In this state, when amounts of compression of the sealing members 282 and 82 are equal to each other while the door portions 280 and 80 are in the closed state, the gap between the main body of the door portion 280 and the side wall 81w can be further reduced as described above. Therefore, the state of the deposited film formed on the surface of the door portion 280 may be slightly different from that of the first embodiment.

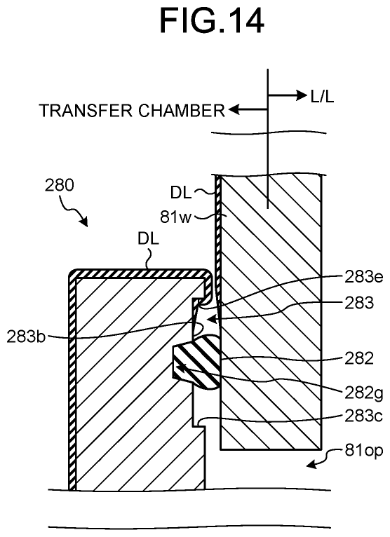

FIG. 14 is a cross-sectional view illustrating an example of the deposited film DL formed on the door portion 280 of the transfer chamber according to the second embodiment, the door portion 280 being provided between the transfer chamber and the L/L.

As illustrated in FIG. 14, the deposited film DL is formed not only on a surface of the door portion 280 facing the transfer chamber and on end surfaces of the door portion 280 in a vertical direction but also, for example, on a part of the surface of the door portion 280 facing the L/L.

However, as described above, the gap between the main body of the door portion 280 and the side wall 81w is smaller, for example, than that in the first embodiment, reducing the amount of the atmosphere containing the reaction products and flowing into this gap, further reducing, for example, an amount of the deposited film DL formed in the gap.

Therefore, the atmosphere containing the reaction products flows into and remains in the space of the groove portion 283, consuming the reaction products in the atmosphere, suppressing the formation of the deposited film DL on the surface of the sealing member 282 facing the step 283e of the groove portion 283.

In the plasma processing apparatus according to the second embodiment, the sealing member 282 of the door portion 280 is arranged in the groove portion 283. This configuration makes it possible to further suppress the generation of the particles from the door portion 280.

### First and Second Modifications

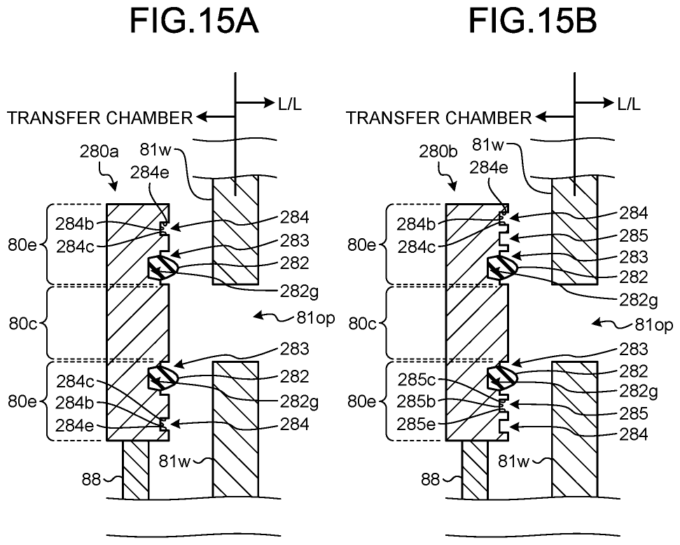

Next, door portions 280a and 280b according to first and second modifications will be described with reference to FIGS. 15A and 15B. The door portions 280a and 280b according to the first and second modifications are each different from the door portion 80 of the first embodiment described above in that the door portions each include a plurality of groove portions.

FIGS. 15A and 15B are cross-sectional views illustrating examples of configurations of the door portions 280a and 280b of the transfer chambers according to the first and second modifications of the second embodiment, the door portions 280a and 280b each being provided between the transfer chamber and the L/L. Note that in FIGS. 15A and 15B, the same reference numerals and symbols are assigned to the same configurations to those of the second embodiment described above, and the description thereof will be omitted.

FIG. 15A is a cross-sectional view illustrating an example of a configuration of the door portion 280a according to the first modification. As illustrated in FIG. 15A, in addition to the configuration of the door portion 280 of the second embodiment described above, the door portion 280a includes a groove portion 284 that surrounds the inside area 80c at a position farther away from the inside area 80c than the groove portion 283.

In other words, the groove portion 284 is provided in the peripheral area 80e of the door portion 280a, and surrounds at least part of the inside area 80c. The groove portion 284 includes a step 284e on a side farther away from the inside area 80c, a step 284c on a side closer to the inside area 80c than the step 284e, and a bottom surface 284b between these steps 284e and 284c.

However, the steps 284e and 284c may be directly connected so that the groove portion 284 may not have the bottom surface 284b. In addition, the groove portion 284 may continuously or intermittently surround the inside area 80c, for example, similarly to the groove portion 83 of FIG. 3B described above or the groove portion 183c of FIG. 8 described above. Alternatively, the groove portion 284 may surround part of the inside area 80c, similarly to the groove portions 183a or 183b of FIG. 6 or 7 described above.

The groove portion 283 is arranged closer to the inside area 80c than the groove portion 284, is provided in the peripheral area 80e of the door portion 280a, and continuously surrounds the inside area 80c. The sealing member 282 is arranged in the groove portion 283.

FIG. 15B is a cross-sectional view illustrating an example of a configuration of the door portion 280b according to the second modification. As illustrated in FIG. 15B, in addition to the configuration of the door portion 280a of the first modification described above, the door portion 280b includes a groove portion 285 that surrounds the inside area 80c at a position farther away from the inside area 80c than the groove portion 283 and closer to the inside area 80c than the groove portion 284.

In other words, the groove portion 285 is provided in the peripheral area 80e of the door portion 280b, and surrounds at least part of the inside area 80c. The groove portion 285 includes a step 285e on a side farther away from the inside area 80c, a step 285c on a side closer to the inside area 80c than the step 285e, and a bottom surface 285b between these steps 285e and 285c. However, the steps 285e and 285c may be directly connected so that the groove portion 285 may not have the bottom surface 285b.

Furthermore, in the door portion 280b according to the second modification, at least any of the groove portions 284 and 285 may continuously or intermittently surround the inside area 80c, and at least any of the groove portions 284 and 285 may surround part of the inside area 80c.

In other words, the arrangement of the groove portions 284 and 285 may be similar to, for example, the arrangement of the groove portions 83 and 84 of FIG. 9B or the arrangement of the groove portions 83 and 184e of FIG. 10, which is described above. Alternatively, the arrangement of the groove portions 284 and 285 may similar to the arrangement of the groove portions 183f and 184f of FIG. 11 described above or the arrangement of the groove portions 183g and 184g of FIG. 12 described above.

According to the plasma processing apparatuses of the first and second modifications, the door portions 280a and 280b further include one of or a plurality of the groove portions 284 and 285, in addition to the groove portion 283. This configuration makes it possible to further suppress the generation of the particles from the door portions 280a and 280b.

Note that, the door portion is not limited to the example of the door portion 280b of the second modification, and may have four or more groove portions surrounding the inside area 80c in a multiple manner. In this case, the sealing member 282 is arranged in the groove portion closest to the inside area 80c. At least one of the plurality of groove portions excluding the groove closest to the inside area 80c may surround part of the inside area 80c or intermittently surround the inside area 80c.

### Third Embodiment

Hereinafter, a third embodiment will be described in detail with reference to the drawings. A plasma processing apparatus according to the third embodiment is different from the plasma processing apparatuses according to the first and second embodiments in that a door portion having a protruding portion is provided.

### Configuration Example of Door Portion

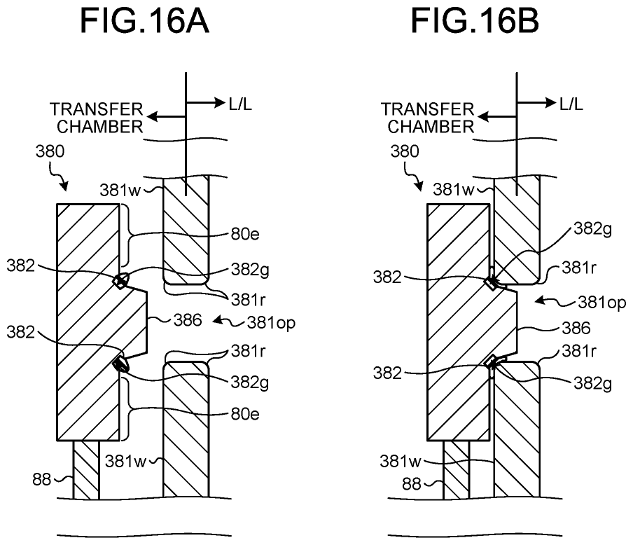

FIGS. 16A and 16B are cross-sectional views each illustrating an example of a configuration of the door portion 380 of the transfer chamber according to the third embodiment, the door portion 380 being provided between the transfer chamber and the L/L. FIG. 16A illustrates a cross-section of the door portion 380 in an opened state, and FIG. 16B illustrates a cross-section of the door portion 380 in a closed state. Note that in FIGS. 16A and 16B, the same reference numerals and symbols are assigned to the same configurations to those of the first embodiment described above, and the description thereof will be omitted.

As illustrated in FIGS. 16A and 16B, the door portion 380 is formed into, for example, a rectangular flat plate shape having the protruding portion 386, and includes a sealing member 382 and a shallow groove 382g. The protruding portion 386 is arranged inside the peripheral area 80e of the door portion 380, and protrudes toward an opening portion 381op provided in a side wall 381w while the door portion 380 is in the closed state.

Here, the peripheral area 80e of the door portion 380 includes a facing surface that faces the side wall 381w around the opening portion 381op while the door portion 380 is in the closed state. Furthermore, a flat plate-like portion of the door portion 380 including the facing surface corresponds to a base portion with respect to the protruding portion 386.

Furthermore, when the door portion 380 is in the closed state, the angle between the facing surface of the door portion 380 facing the side wall 381w around the opening portion 381op and a side surface of the protruding portion 386 is, for example, 90° or more and 100° or less. This configuration suppress contact between the end portions of the side wall 381w near the opening portion 381op and the protruding portion 386, in the opening/closing operation of the door portion 380.

The sealing member 382 is arranged along the base of the protruding portion 386 to continuously surround the protruding portion 386. More specifically, the shallow groove 382g continuously surrounding the protruding portion 386 is formed in the base of the protruding portion 386, and the sealing member 382 is embedded in the shallow groove 382g by, for example, hot compression molding or the like, similarly to the sealing member 82 of first embodiment described above.

Therefore, the sealing member 382 is configured to be protruded from a recessed corner portion that is formed by the facing surface of the door portion 380 facing the side wall 381w and the side surface of the protruding portion 386. At this time, the sealing member 382 may protrude so that the thickness in the width direction decreases toward the front end. Furthermore, as described later, from the viewpoint of a sealing method using the sealing member 382, the sealing member 382 preferably has a relatively small amount of protrusion.

As illustrated in FIG. 16B, while the door portion 380 is in the closed state, the facing surface described above is closer to the side wall 381w around the opening portion 381op across a small gap. In addition, the protruding portion 386 of the door portion 380 protrudes toward the opening portion 381op, and the corner portion between the facing surface of the door portion 380 and the side surface of the protruding portion 386 is closer to an end portion 381r of the side wall 381w near the opening portion 381op side and on a side facing the transfer chamber.

Due to this configuration, the sealing member 382 arranged along the base of the protruding portion 386 touches on and is compressed against the end portion 381r of the side wall 381w, and the L/L is airtightly sealed. As described above, the sealing method of compressing the end portion 381r of the side wall 381w toward the sealing member 382 makes it possible to obtain a sealing property even if the amount of protrusion of the sealing member 382 is small as described above.

Here, of the end portion 381r on the transfer chamber side and the end portion 381r on the L/L side of the side wall 381w that are provided to surround the opening portion 381op, at least the end portion 381r on the transfer chamber side may be formed into a curved surface shape. In other words, of the two end portions 381r of frame shape of the side wall 381w, at least the end portion 381r on a side touching on the sealing member 382 may be formed into a curved surface shape.

This configuration makes it possible to further improve the sealing property by the sealing member 382, enhancing airtightness of the L/L. In addition, an amount of deformation of the sealing member 382 touching on the end portion 381r of the side wall 381w can be suppressed, extending the life of the sealing member 382.

The sealing member 382 is a consumable having a shorter life than other configurations of the door portion 380. Furthermore, as described above, the sealing member 382 is formed in the shallow groove 382g by, for example, hot compression molding or the like, and it may be difficult to remove and replace the sealing member 382 that has exceed the life span, from the door portion 380. In this case, when the life of the sealing member 382 expires, the door portion 380 itself is to be replaced.

As described above, the long life of the sealing member 382 leads to the long life of the door portion 380 itself.

Note that as illustrated in FIGS. 16A and 16B, the end portion 381r of the side wall 381w on the L/L side may also be formed in a curved shape.

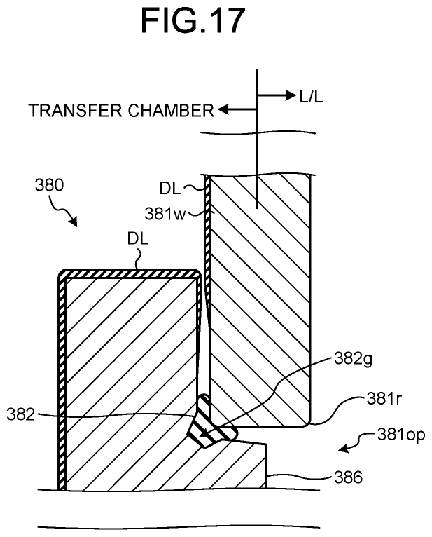

FIG. 17 is a cross-sectional view illustrating an example of the deposited film DL formed on the door portion 380 of the transfer chamber according to the third embodiment, the door portion 380 being provided between the transfer chamber and the L/L.

As illustrated in FIG. 17, the deposited film DL is formed not only on a surface of the door portion 380 facing the transfer chamber and on end surfaces of the door portion 380 in a vertical direction but also, for example, on a part of the surface of the door portion 380 facing the L/L.

However, while the door portion 380 is in the closed state, the sealing member 382 is arranged further inward the door portion 380 and, for example, closer to the end portion 381r of the side wall 381w near the opening portion 381op.

Therefore, the reaction products in the atmosphere flowing into the gap between the door portion 380 and the side wall 381w forms the deposited film DL on surfaces of the door portion 380 and side wall 381w facing each other outside the sealing member 382, and is consumed without reaching, for example, the sealing member 382. Therefore, the formation of the deposited film DL on the surface of the sealing member 382 facing the gap is suppressed.

An exposed area of the sealing member 382 arranged along the base of the protruding portion 386 is narrowed, for example, within a direction defined by an angle of 90° or more and 100° or less, according to the angle of the protruding portion 386 protruding from the facing surface of the door portion 380. As described above, in the sealing member 382, the exposed area itself in which the deposited film DL can be formed is reduced, thus further suppressing the formation of the deposited film DL on the sealing member 382.

Furthermore, as described above, the amount of protrusion of the sealing member 382 is relatively small, and the amount of deformation of the sealing member 382 upon touch on the end portion 381r of the side wall 381w can be also relatively reduced. Furthermore, in a case where the end portion 381r of the side wall 381w is formed into the curved shape, the amount of deformation of the sealing member 382 is further reduced.

Accordingly, in a case where the compressed sealing member 382 returns to the original shape when the door portion 380 is opened, as well, it is considered that a change in shape of the sealing member 382 is relatively small, and the influence of the elastic force generated at this time is also relatively small. Therefore, even if the deposited film DL attaches to the sealing member 382, peeling, scattering, and the like of the deposited film DL from the sealing member 382 are suppressed.

In the plasma processing apparatus according to the third embodiment, the door portion 380 includes the base portion of flat plate shape that includes the facing surface facing the side wall 381w in the peripheral area 80e, the protruding portion 386 that protrudes toward the opening portion 381op in the side wall 381w, and the sealing member 382 that is arranged along the base of the protruding portion 386 to continuously surround the protruding portion 386. This configuration makes it possible to further suppress the generation of the particles from the door portion 380.

In the plasma processing apparatus according to the third embodiment, the angle between the facing surface of the door portion 380 facing the side wall 381w, and the side surface of the protruding portion 386 is 90° or more and 100° or less. This configuration suppresses interference of the protruding portion 386 with the end portion 381r or the like of the side wall 381w in the opening/closing operation of the door portion 380.

In the plasma processing apparatus according to the third embodiment, the sealing member 382 is arranged at a corner portion between the facing surface of the door portion 380 facing the side wall 381w, and a side surface of the protruding portion 386. This configuration makes it possible to reduce an exposed surface of the sealing member 382 on which the deposited film DL may be formed, further suppressing the generation of the particles from the door portion 380.

In the plasma processing apparatus according to the third embodiment, the sealing member 382 touches on the end portion 381r of the side wall 381w near the opening portion 381op when the door portion 380 is in the closed state. This configuration can reduce the amount of compression of the sealing member 382, suppress the peeling and scattering of the particles, and extend the life of the sealing member 382.

### First and Second Modifications

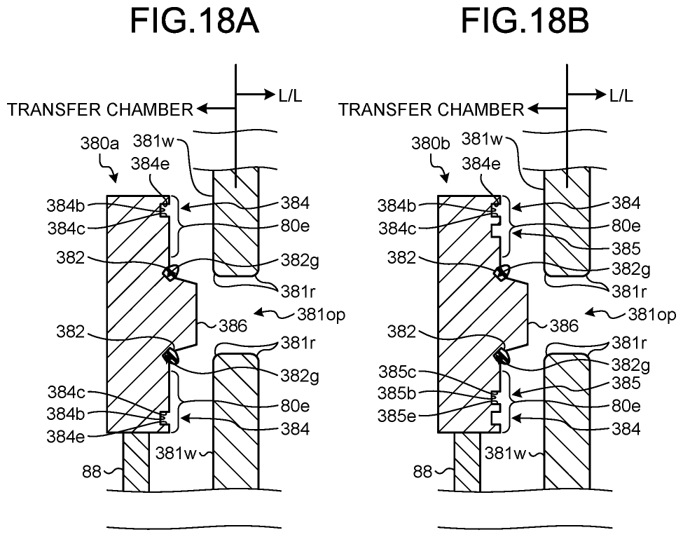

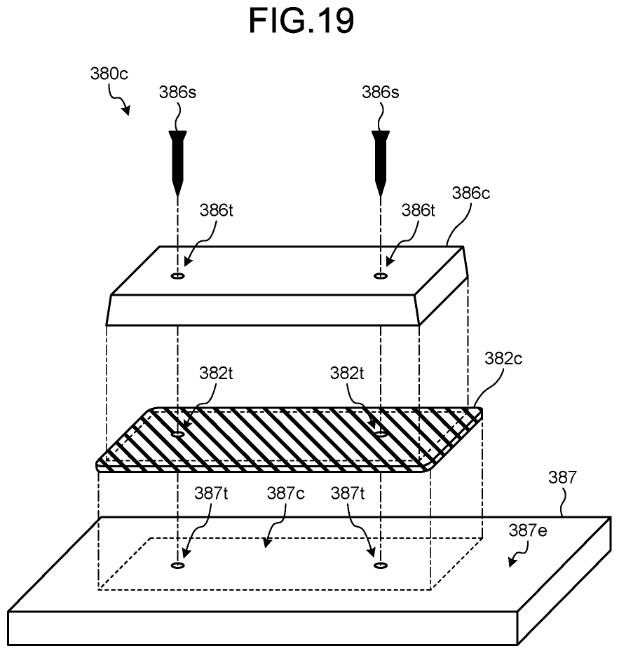

Next, door portions 380a and 380b according to first and second modifications will be described with reference to FIGS. 18A and 18B. The door portions 380a and 380b according to the first and second modifications are different from the door portion 380 of the third embodiment described above in that a groove portion 384 and the like are provided.

FIGS. 18A and 18B are cross-sectional views illustrating examples of configurations of the door portions 380a and 380b of the transfer chambers according to the first and second modifications of the third embodiment, the door portions 380a and 380b each being provided between the transfer chamber and the L/L. Note that in FIGS. 18A and 18B, the same reference numerals and symbols are assigned to the same configurations to those of the third embodiment described above, and the description thereof will be omitted.

FIG. 18A is a cross-sectional view illustrating an example of a configuration of the door portion 380a according to the first modification. As illustrated in FIG. 18A, in addition to the configuration of the door portion 380 of the third embodiment described above, the door portion 380a includes the groove portion 384 that is provided in the base portion outside the sealing member 382 to surround the sealing member 382.

In other words, the groove portion 384 is provided in the peripheral area 80e in the base portion of the door portion 380a with respect to the protruding portion 386, and surrounds at least part of the sealing member 382. In addition, the groove portion 384 includes a step 384e on a side farther away from the protruding portion 386, a step 384c on a side closer to the protruding portion 386 than the step 384e, and a bottom surface 384b between these steps 384e and 384c.

However, the steps 384e and 384c may be directly connected so that the groove portion 384 may not have the bottom surface 384b. In addition, the groove portion 384 may continuously or intermittently surround the sealing member 382, for example, similarly to the groove portion 83 of FIG. 3B described above or the groove portion 183c of FIG. 8 described above. Alternatively, the groove portion 384 may surround part of the sealing member 382, similarly to the groove portions 183a or 183b of FIG. 6 or 7 described above.

FIG. 18B is a cross-sectional view illustrating an example of a configuration of the door portion 380b according to the second modification. As illustrated in FIG. 18B, in addition to the configuration of the door portion 380a of the first modification described above, the door portion 380b includes a groove portion 385 that is provided in the base portion closer to the protruding portion 386 than the groove portion 384 to surround the sealing member 382.

In other words, in the base portion of the door portion 380a with respect to the protruding portion 386, the groove portion 385 is provided in the peripheral area 80e closer to the protruding portion 386 than the groove portion 384, and surrounds at least part of the sealing member 382. In addition, the groove portion 385 includes a step 385e on a side farther away from the protruding portion 386, a step 385c on a side closer to the protruding portion 386 than the step 385e, and a bottom surface 385b between these steps 385e and 385c. However, the steps 385e and 385c may be directly connected so that the groove portion 385 may not have the bottom surface 385b.

Furthermore, in the door portion 380b according to the second modification, at least any of the groove portions 384 and 385 may continuously or intermittently surround the sealing member 382, and at least any of the groove portions 384 and 385 may surround part of the sealing member 382.

In other words, the arrangement of the groove portions 384 and 385 may be similar to, for example, the arrangement of the groove portions 83 and 84 of FIG. 9B or the arrangement of the groove portions 83 and 184e of FIG. 10, which is described above. Alternatively, the arrangement of the groove portions 384 and 385 may be similar to the arrangement of the groove portions 183f and 184f of FIG. 11 described above or the arrangement of the groove portions 183g and 184g of FIG. 12 described above.

In these configurations, it is preferable to arrange a plurality of groove portions 384 and 385 in a double manner at a boundary between portions where the groove portions 384 and 385 are arranged, or to arrange any of the plurality of groove portions 384 and 385 at positions corresponding to portions where the other of the groove portions 384 and 385 breaks, when viewed from the center side of the protruding portion 386. Here, the center side of the protruding portion 386 represents the center position of the protruding portion 386 in plan view of the door portion 380.

In the plasma processing apparatuses according to the first and second modifications, the door portions 380a and 380b include one of or a plurality of groove portions 384 and 385. This configuration makes it possible to further suppress the generation of the particles from the door portions 380a and 380b.

### Third Modification

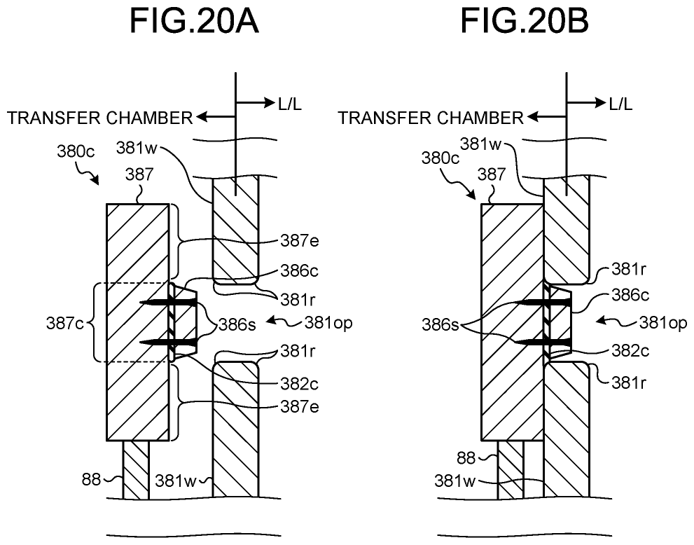

Next, a door portion 380c according to a third modification will be described with reference to FIGS. 19 to 20B. The door portion 380c according to the third modification is different from the door portion 380 of third embodiment described above in that a protruding member 386c removable from the main body of the door portion 380c is provided.

FIG. 19 is a perspective view of the door portion 380c of the transfer chamber according to the third modification of the third embodiment, the door portion 380c being provided between the transfer chamber and the L/L. Note that in FIG. 19, the same reference numerals and symbols are assigned to the same configurations to those of the third embodiment described above, and the description thereof will be omitted.

As illustrated in FIG. 19, the door portion 380c according to the third modification includes a plate-like member 387, a sealing member 382c, the protruding member 386c, and a plurality of screws 386s.

The plate-like member 387 as the base portion is, for example, an aluminum member, and is configured into a rectangular flat plate shape. The plate-like member 387 may have a film such as an aluminum oxide film on a base material such as aluminum. Furthermore, the plate-like member 387 has a peripheral area 387e and an inside area 387c on a surface facing toward the L/L.

The peripheral area 387e includes the facing surface facing the side wall between the transfer chamber and the L/L. The inside area 387c is surrounded by the peripheral area 387e and arranged inside the peripheral area 387e. The inside area 387c includes a surface that is continued to the facing surface facing the side wall described above and on which the protruding member 386c is arranged via the sealing member 382c as described later.

Furthermore, the inside area 387c of the plate-like member 387 is provided with a plurality of screw holes 387t that reaches a predetermined depth in the plate-like member 387.

The sealing member 382c includes, for example, an elastic resin material or the like that is molded into a substantially rectangular sheet shape. The sealing member 382c is arranged in the inside area 387c that is a surface of the plate-like member 387 facing toward the L/L, and is interposed between the plate-like member 387 and the protruding member 386c to airtightly seal the L/L.

Furthermore, the sealing member 382c is provided with a plurality of screw holes 382t that penetrates the sealing member 382c. The plurality of screw holes 382t is provided at positions where the plurality of screw holes 382t is aligned with the plurality of screw holes 387t of the plate-like member 387 in a state where the sealing member 382c is arranged on the plate-like member 387.

The protruding member 386c is, for example, an aluminum member, and is configured into a rectangular flat plate shape. The protruding member 386c may have a film such as an aluminum oxide film, on a base material such as aluminum. The protruding member 386c being arranged on the plate-like member 387 has a side surface that is inclined at an angle of 90° or more and 100° or less with respect to the facing surface of the plate-like member 387 facing the side wall.

The protruding member 386c is arranged on a surface facing toward the L/L, in the inside area 387c of the plate-like member 387, via the sealing member 382c. The sealing member 382c described above is formed to be slightly larger than the surface of the protruding member 386c on a side to be arranged on the plate-like member 387. Therefore, the surplus portion of the sealing member 382c continuously surrounds the base of the protruding member 386c.

Furthermore, the protruding member 386c is provided with a plurality of screw holes 386t that penetrates the protruding member 386c. The plurality of screw holes 386t is provided at positions where the plurality of screw holes 386t is aligned with the plurality of screw holes 382t of the sealing member 382c and the plurality of screw holes 387t of the plate-like member 387, in a state where the protruding member 386c is arranged on the plate-like member 387 via the sealing member 382c.

While the door portion 380c is in the closed state, the protruding member 386c arranged in the inside area 387c of the plate-like member 387 protrudes to the opening portion provided in the side wall between the transfer chamber and the L/L. As described above, the protruding member 386c is removable from the plate-like member 387, and has a similar function to that of the protruding portion 386 in the door portion 380 of the third embodiment described above.

The screws 386s as a fastening member fasten the protruding member 386c to the plate-like member 387 via the sealing member 382c. The screw 386s are made of, for example, aluminum or stainless-steel SUS.

The example of FIG. 19 shows a configuration in which two screws 386s are horizontally aligned for fastening, near the center of the protruding member 386c. As described above, preferably, the plurality of screws 386s can be used for fastening.

However, any number of the screws 386s and any arrangement of the screws 386s may be employed. For example, a configuration may be provided in which one screw 386s is fastened at the center position of the protruding member 386c. Furthermore, for example, a configuration may be provided in which three screws 386s are arranged at the apexes of a triangle in top view. For example, a configuration may be provided in which four screws 386s are arranged near four corners of a rectangular protruding member 386c respectively.

Note that in any configuration, it is preferable to arrange the screw 386s so that a substantially uniform force is applied to the entire surface of the sealing member 382c positioned between the plate-like member 387 and the protruding member 386c and the sealing member 382c is substantially uniformly compressed. This configuration makes it possible to provide a substantially uniform sealing property in the circumferential direction of the protruding member 386c, maintaining sufficient airtightness of the L/L.

FIGS. 20A and 20B each illustrate the door portion 380c having a combination of the plate-like member 387, the sealing member 382c, the protruding member 386c, and a plurality of screws 386s.

FIGS. 20A and 20B are cross-sectional views illustrating an example of a configuration of the door portion 380c of the transfer chamber according to the third modification of the third embodiment, the door portion 380c being provided between the transfer chamber and the L/L. FIG. 20A illustrates a cross-section of the door portion 380c in an opened state, and FIG. 20B illustrates a cross-section of the door portion 380c in a closed state.

As illustrated in FIGS. 20A and 20B, in a state where the plate-like member 387, the sealing member 382c, the protruding member 386c, and the plurality of screws 386s are combined, the plurality of screws 386s penetrates the protruding member 386c and the sealing member 382c and reaches a predetermined depth of the plate-like member 387. Therefore, the protruding member 386c is fixed to the plate-like member 387 via the sealing member 382c.

Furthermore, in a state where the plate-like member 387, the sealing member 382c, the protruding member 386c, and the plurality of screws 386s are combined, the surplus portion of the sealing member 382c continuously surrounds the base of the protruding member 386c. In other words, the surplus portion of the sealing member 382c is arranged at a corner portion between the facing surface of the plate-like member 387 facing the side wall 381w, and a side surface of the protruding member 386c.

As illustrated in FIG. 20B, in a state where the door portion 380c is in the closed state, the protruding member 386c protrudes toward the opening portion 381op, and the corner portion between the facing surface of the door portion 380c and the side surface of the protruding member 386c is closer to the end portion 381r of the side wall 381w near the opening portion 381op side. Due to this configuration, the surplus portion of the sealing member 382c around the base of the protruding member 386c touches on and is compressed against the end portion 381r of the side wall 381w, and the L/L is airtightly sealed.

In the plasma processing apparatus according to the third modification, the door portion 380c includes the plate-like member 387, the protruding member 386c arranged on the surface of the plate-like member 387, and the sealing member 382c of sheet shape interposed between the plate-like member 387 and the protruding member 386c.

Similarly to the sealing member 82 and the like described above, the sealing member 382c is also a consumable having a shorter life than other members of the door portion 380c. As described above, the door portion 380c includes the plate-like member 387, the protruding member 386c, the sealing member 382c, and the like which are removable from each other. Therefore, the sealing member 382c, the life of which expires, is allowed to be removed and replaced from the door portion 380c. Therefore, it is possible to extend the life of the door portion 380c itself.

Furthermore, the plasma processing apparatus according to the third modification has similar effects to those of the door portion 380 according to the third embodiment described above.

### Fourth and Fifth Modifications

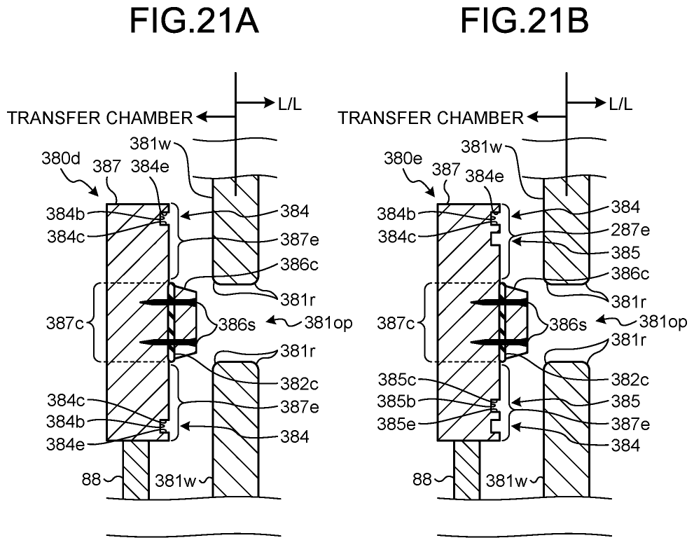

Even in a case where each member is removable similarly to the door portion 380c of the third modification, for example, one or more groove portions can be arranged in the plate-like member 387. FIGS. 21A and 21B illustrate door portions 380d and 380e according to fourth and fifth modifications that include one or more groove portions 384 and 385 and the like.

FIGS. 21A and 21B are cross-sectional views illustrating examples of configurations of the door portions 380d and 380e of the transfer chambers according to the fourth and fifth modifications of the third embodiment, the door portions 380d and 380e each being provided between the transfer chamber and the L/L. Note that in FIGS. 21A and 21B, the same reference numerals and symbols are assigned to the same configurations to those of the third modification described above, and the description thereof will be omitted.

FIG. 21A is a cross-sectional view illustrating an example of a configuration of the door portion 380d according to the fourth modification. As illustrated in FIG. 21A, in addition to the configuration of the door portion 380c of the third modification described above, the door portion 380d includes the groove portion 384 that is provided in the peripheral area 387e outside the sealing member 382c to surround the sealing member 382c.

In other words, with respect to the groove portion 384, the door portion 380d according to the fourth modification has a configuration corresponding to the configuration of the door portion 380a according to the first modification described above in which the respective members are integrally formed.

FIG. 21B is a cross-sectional view illustrating an example of a configuration of the door portion 380e according to the fifth modification. As illustrated in FIG. 21B, in addition to the configuration of the door portion 380d according to the fourth modification described above, the door portion 380e includes the groove portion 385 that is provided in the peripheral area 387e closer to the protruding member 386c than the groove portion 384 to surround the sealing member 382c.

In other words, with respect to the groove portions 384 and 385, the door portion 380e according to the fifth modification has a configuration corresponding to the configuration of the door portion 380b according to the second modification described above in which the respective members are integrally formed.

In the plasma processing apparatuses according to the fourth and fifth modifications, the door portions 380d and 380e include one of or a plurality of groove portions 384 and 385. This configuration makes it possible to further suppress the generation of the particles from the door portions 380d and 380e.

Note that in the first to third embodiments and modifications thereof described above, the plasma processing apparatuses each include the process chamber connected to the transfer chamber, the L/L storing the wafer to be processed and collecting the processed wafer.

However, each plasma processing apparatus may include a pre-process chamber in which pre-process for plasma processing is performed, a post-process chamber in which post-process is performed, and the other containers. In this case, the configurations of the first to third embodiments and modifications thereof described above may be applied to the door portions provided between these chambers and the like and the transfer chamber.

In the first to third embodiments and modifications thereof, each plasma processing apparatus is, for example, the etching apparatus. However, the plasma processing apparatus may be a plasma chemical vapor deposition (CVD) apparatus, an asking apparatus, or the like. Alternatively, even in a case where plasma is not used, the door portions of the first to third embodiments and modifications thereof described above may be applied to a substrate processing apparatus, such as a thermal CVD apparatus, used for processing that may generate the deposited film.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A substrate processing apparatus comprising:
a first container that is configured to store a substrate;
a second container that is connected to the first container via an opening portion through which the substrate is transferred between the first container and the second container; and
a door portion that is arranged so as to be capable of opening and closing the opening portion from inside the second container and is configured to airtightly seal the first container, wherein
the door portion includes:
a peripheral area that includes a surface facing a side wall of the second container around the opening portion while the door portion is in a closed state;
an inside area that is an area surrounded by the peripheral area and includes a surface facing the opening portion while the door portion is in the closed state;
a groove portion that is provided in the peripheral area to surround at least part of the inside area and includes a first step and a second step, the second step being positioned closer to the inside area than the first step; and
a sealing member that continuously surrounds the inside area at a position closer to the inside area than the first step.

2. The substrate processing apparatus according to claim 1, wherein
the sealing member is arranged closer to the inside area than the second step.

3. The substrate processing apparatus according to claim 1, wherein
the sealing member is arranged in the groove portion.

4. The substrate processing apparatus according to claim 1, wherein
the groove portion includes:
a first groove portion; and
a second groove portion arranged closer to the inside area than the first groove portion, and
the sealing member is arranged closer to the inside area than the first step of the second groove portion.

5. The substrate processing apparatus according to claim 4, wherein
the first groove portion surrounds a first part of the inside area,
the second groove portion surrounds a second part of the inside area other than the first part of the inside area, and
the first and second groove portions are arranged in an overlapping manner at a boundary between the first part and the second part of the inside area when viewed from a center of the inside area.

6. The substrate processing apparatus according to claim 4, wherein
the first and second groove portions intermittently surround the inside area, and
the second groove portion is arranged at positions corresponding to portions where the first groove portion breaks and the first groove portion is arranged at positions corresponding to portions where the second groove portion breaks, when viewed from a center of the inside area.

7. The substrate processing apparatus according to claim 4, wherein
the sealing member is arranged closer to the inside area than the second step of the second groove portion.

8. The substrate processing apparatus according to claim 4, wherein
the sealing member is arranged in the second groove portion.

9. A substrate processing apparatus comprising:
a first container that is configured to store a substrate;
a second container that is connected to the first container via an opening portion through which the substrate is transferred between the first container and the second container; and
a door portion that is arranged so as to be capable of opening and closing the opening portion from inside the second container and is configured to airtightly seal the first container, wherein
the door portion includes:
a base portion that includes a facing surface facing a side wall of the second container around the opening portion while the door portion is in a closed state;
a protruding portion that is arranged in an area surrounded by the facing surface of the base portion and protrudes toward the opening portion while the door portion is in the closed state; and
a sealing member that is arranged along a base of the protruding portion and continuously surrounds the protruding portion.

10. The substrate processing apparatus according to claim 9, wherein
an angle between the facing surface and a side surface of the protruding portion is 90° or more and 100° or less.

11. The substrate processing apparatus according to claim 9, wherein
the sealing member is arranged at a corner portion between the facing surface and a side surface of the protruding portion and touches on an end portion of the side wall near the opening portion while the door portion is in the closed state.

12. The substrate processing apparatus according to claim 9, wherein
the door portion includes a plate-like member including the facing surface, and
the protruding portion is removable from the plate-like member, and is arranged on a surface continued to the facing surface of the plate-like member.

13. The substrate processing apparatus according to claim 12, wherein
the door portion further includes a fastening member that fastens the protruding portion to the plate-like member.

14. The substrate processing apparatus according to claim 12, wherein
the sealing member is formed into a sheet shape having an area larger than that of a surface of the protruding portion on the plate-like member, and
the protruding portion is arranged on the plate-like member via the sealing member.

15. The substrate processing apparatus according to claim 9, wherein
the door portion further includes a groove portion that is provided in the base portion and surrounds at least part of the sealing member.

16. The substrate processing apparatus according to claim 15, wherein
the groove portion includes:
a first groove portion; and
a second groove portion that is arranged closer to the protruding portion than the first groove portion.

17. The substrate processing apparatus according to claim 16, wherein
the first groove portion surrounds a first part of the sealing member,
the second groove portion surrounds a second part of the sealing member other than the first part of the sealing member, and
the first and second groove portions are arranged in an overlapping manner at a boundary between the first part and the second part of the sealing member when viewed from a center side of the protruding portion.

18. The substrate processing apparatus according to claim 16, wherein
the first and second groove portions intermittently surround the sealing member, and
the second groove portion is arranged at positions corresponding to portions where the first groove portion breaks and the first groove portion is arranged at positions corresponding to portions where the second groove portion breaks, when viewed from a center side of the protruding portion.

19. A substrate processing apparatus comprising:
a first container that is configured to store a substrate;
a second container that is connected to the first container via an opening portion through which the substrate is transferred between the first container and the second container; and
a door portion that is arranged so as to be capable of opening and closing the opening portion from inside the second container and is configured to airtightly seal the first container, wherein
the door portion includes:
a plate-like member that includes a first surface portion and a second surface portion surrounded by the first surface portion, the first surface portion facing a side wall of the second container around the opening portion and the second surface portion facing the opening portion while the door portion is in a closed state;
a protruding member that is arranged on the second surface portion of the plate-like member and protrudes toward the opening portion while the door portion is in the closed state; and
a sheet-shaped sealing member that is interposed between the plate-like member and the protruding member, and includes a surplus portion larger than a surface of the protruding member on the plate-like member and continuously surrounding a base of the protruding member.

20. The substrate processing apparatus according to claim 19, wherein
an angle between the first surface portion of the plate-like member and a side surface of the protruding member is 90° or more and 100° or less.
